(19) United States
(12) Patent Application Publication
(10) Pub. No.: US 2021/0391382 A1
(43) Pub. Date: Dec. 16, 2021

(54) INTEGRATED STRUCTURE OF CRYSTAL RESONATOR AND CONTROL CIRCUIT AND INTEGRATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Ningbo, Zhejiang (CN)

(21) Appl. No.: 17/419,666

(22) PCT Filed: Nov. 5, 2019
(86) PCT No.: PCT/CN2019/115658

§ 371 Date: Jun. 29, 2021

(30) Foreign Application Priority Data
Dec. 29, 2018 (CN) 201811647884.4

(51) Int. Cl. H01L 27/20; H03H 3/02; H03H 9/05; H03H 9/10; H03H 9/17; H03H 9/19

(52) U.S. Cl. CPC H01L 27/20; H03H 3/02; H03H 9/0547; H03H 2003/021; H03H 9/173; H03H 9/19; H03H 9/1014

(57) ABSTRACT

An integrated structure of a crystal resonator with a control circuit and an integration method therefor. The crystal resonator is formed by first forming a lower cavity (120) in a device wafer (100) in which a control circuit is formed, forming a piezoelectric vibrator (200) on the device wafer (100) and then enclosing the piezoelectric vibrator (200) within an upper cavity (400) through forming a cap layer (420) using a planar fabrication process, The crystal resonator according to the present invention has a smaller size, which is help for reducing the power consumption thereof, and the crystal resonator is more easily integrated with other semiconductor components, thereby improving the integration of the device.

### TECHNICAL FIELD

The present invention relates to the technical field of semiconductor and, in particular, to an integrated structure of crystal resonator and control circuit and an integration method therefor.

### BACKGROUND

A crystal resonator is a device operating on the basis of inverse piezoelectricity of a piezoelectric crystal. As key components in crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, it is difficult to integrate existing crystal resonators with other semiconductor components, and also the sizes of the existing crystal resonators are relatively large.

For example, commonly used existing crystal resonators include surface-mount ones, in which a base is bonded with a metal solder (or an adhesive) to a cover to form a hermetic chamber in which a piezoelectric vibrator is housed. in addition, electrodes for the piezoelectric vibrator are electrically connected to an associated circuit via solder pads or wires. Further shrinkage of such crystal resonators is difficult, and their electrical connection to the associated circuit by soldering or gluing additionally hinders their miniaturization.

### SUMMARY OF THE INVENTION

It is an object of the present invention to provide a method for integrating a crystal resonator with a control circuit, which overcomes the above described problems with conventional crystal resonators, i.e., a bulky size and difficult integration.

To solve the problem, the present invention provides a method for integrating a crystal resonator with a control circuit, comprising:

providing a device wafer in which the control circuit is formed, and etching the device wafer to form a lower cavity for the crystal resonator;

forming a piezoelectric vibrator comprising a top electrode, a piezoelectric crystal and a bottom electrode on a front side of the device wafer above the lower cavity;

forming a connecting structure on the device wafer, wherein the connecting structure electrically connects the top electrode and the bottom electrode of the piezoelectric vibrator to the control circuit; and

forming a cap layer on the front side of the device wafer, wherein the cap layer covers the piezoelectric vibrator, and the cap layer together with the piezoelectric vibrator and the device wafer delimits an upper cavity for the crystal resonator.

It is a further object of the present invention to provide an integrated structure of a crystal resonator and a control circuit, comprising:

a device wafer in which the control circuit and a lower cavity are formed, wherein the lower cavity is exposed at a front side of the device wafer;

a piezoelectric vibrator comprising a top electrode, a piezoelectric crystal and a bottom electrode, wherein the piezoelectric vibrator is formed on the front side of the device wafer above the lower cavity;

a connecting structure configured to electrically connect the top and bottom electrodes of the piezoelectric vibrator to the control circuit; and

a cap layer which is formed on the front side of the device wafer and covers the piezoelectric vibrator, wherein the cap layer together with the piezoelectric vibrator and the device wafer delimits an upper cavity for the crystal resonator.

In the method of the present invention, the crystal resonator and the control circuit are integrated on the same device wafer, which is accomplished by first forming the lower cavity in the device wafer containing the control circuit using a planar fabrication process, forming the piezoelectric vibrator on the device wafer and then enclosing the piezoelectric vibrator within the upper cavity through forming the cap layer using another planar fabrication process. As such, compared with traditional crystal resonators (e.g., surface-mount ones), in addition to being able to integrate with other semiconductor components with a higher degree of integration, the crystal resonator produced using the method of the present invention is more compact or miniaturized in size and hence less costly and less power-consuming.

### BRIEF DESCRIPTION OF THE DRAWINGS

FIG. 1 shows a flowchart schematically illustrating a method for integrating a. crystal resonator with a control circuit according to an embodiment of the present invention.

FIGS. 2a to 2j are schematic representations of structures resulting from steps in a method for integrating a crystal resonator with a control circuit according to an embodiment of the present invention.

In these figures,

100 denotes a device wafer; AA, a device area; 100A, an initial crystal; 100B, a dielectric layer; 110, a control circuit; 111, a first circuit; 111T, a first transistor; 111C, a first interconnecting structure; 112, a second circuit; 112T, a first transistor; 112C, a first interconnecting structure; 120, a lower cavity; 200, a piezoelectric vibrator; 210, a bottom electrode; 220, a piezoelectric crystal; 230, a top electrode; 300, an encapsulation layer; 300a, a through hole; 310, a conductive plug; 320, an interconnecting wire; 400, an upper cavity; 410, a sacrificial layer; 420, a cap layer; 420a, an opening; 421, a cap material layer; and 430, a closure plug.

### DETAILED DESCRIPTION

The core idea of the present invention is to provide an integrated structure of a crystal resonator and a control circuit and an integration method therefor, in which planar fabrication processes are utilized to form the crystal resonator and integrate it onto a device wafer where the control circuit is formed. This, on the one hand, results in a size reduction of the crystal resonator and, on the other hand, allows an increased degree of integration of the crystal resonator with other semiconductor components.

Specific embodiments of the structure and method proposed in the present invention will be described below in greater detail with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

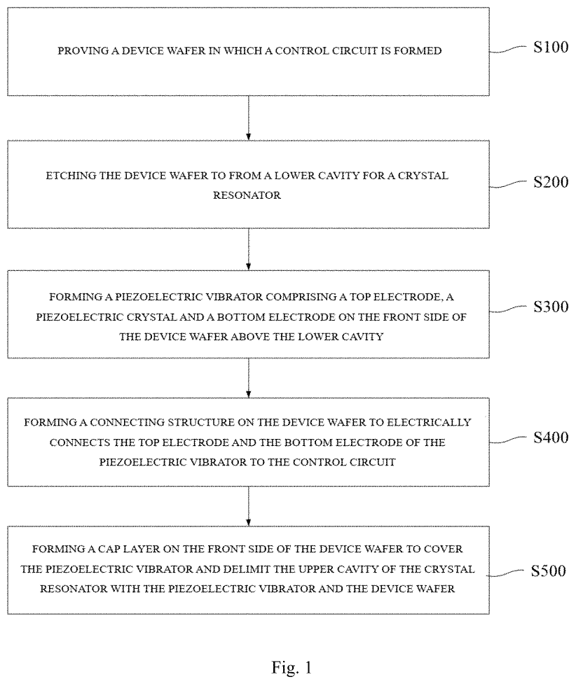

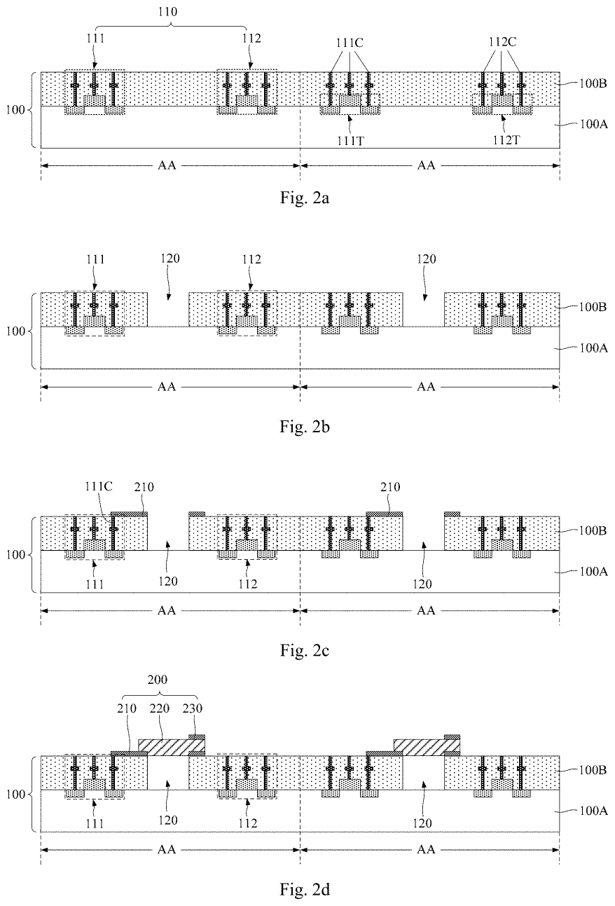

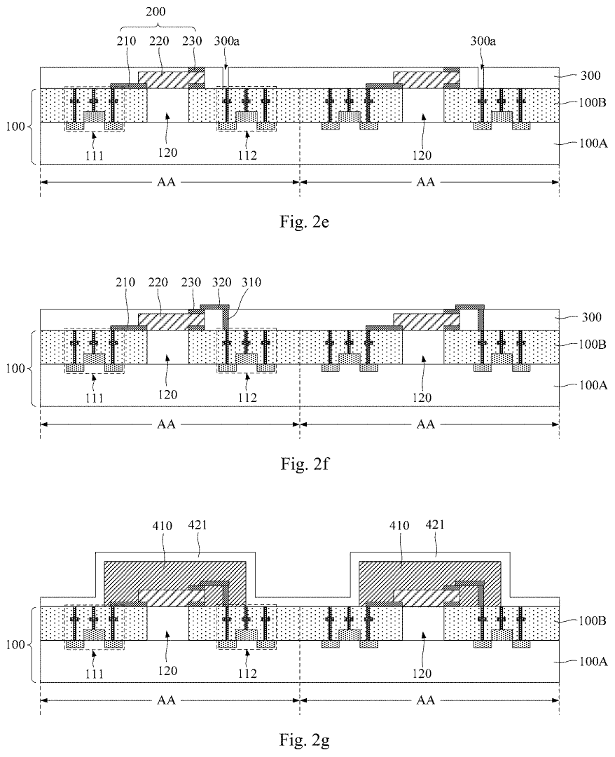

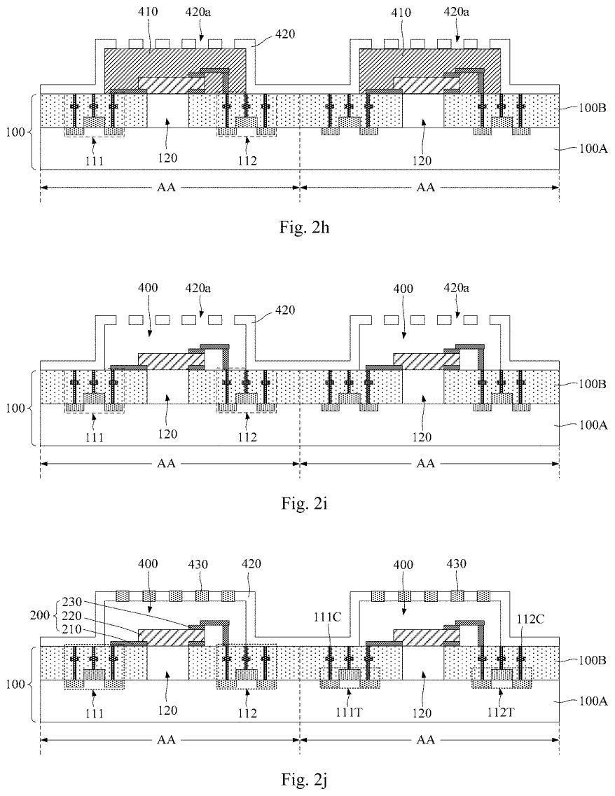

FIG. 1 shows a flowchart schematically illustrating a method for integrating a crystal resonator with a control circuit according to an embodiment of the present invention, and FIGS. 2a to 2j are schematic representations of structures resulting from steps in the method for integrating a crystal resonator with a control circuit according to an embodiment of the present invention, In the following, steps for forming the crystal resonator will be described in detail with reference to the figures.

In step S100, with reference to FIG. 2a, a device wafer 1.00 is provided, in which a control circuit 110 is formed. The control circuit 110 may be configured to apply an electrical signal to the subsequently formed piezoelectric vibrator.

The control circuit 110 may include a first circuit 111 and a second circuit 112, Which may be electrically connected to a top electrode and a bottom electrode of the subsequently formed piezoelectric vibrator, respectively.

With continued reference to FIG. 2a. the first circuit 111 may include a first transistor 111T and a first interconnecting structure 111C. The first transistor 111T may be buried within the device wafer 100, and the first interconnecting structure 111C may be connected to the first transistor 111T and extend to a front side of the device wafer 100. The first interconnecting structure 111C may include conductive plugs electrically connected respectively to a gate, source and drain of the first transistor 111T.

Similarly, the second circuit 112 may include a second transistor 112T and a second interconnecting structure 112C. The second transistor 112T may be buried within the device wafer 100, and the second interconnecting structure 112C may be connected to the second transistor 112T and extend to the front side of the device wafer 100. The second interconnecting structure 112C may include conductive plugs electrically connected respectively to a gate, source and drain of the second transistor 112T.

The formation of the control circuit 110 may include:

providing a substrate wafer 100A, and forming a first transistor . T and a second transistor 112T on the substrate wafer 100A and

then, forming a dielectric layer 100B on the substrate wafer 100A to cover the first transistor 1117 and the second transistor 112T, and forming a first interconnecting structure 111C and a second interconnecting structure 112C in the dielectric layer 100B, resulting in the formation of the device wafer 100.

In other words, the device wafer 100 includes the substrate wafer 100A and the dielectric layer 100B formed thereon, and the first transistor 111T and the second transistor 112T are both formed on the substrate wafer 100A. Additionally, the dielectric layer 100B covers the first transistor 111T and the second transistor 112T, and each of the first interconnecting structure 111C and the second interconnecting structure 112C are formed in the dielectric layer 100B and extends to the surface of the dielectric layer 100B.

The substrate wafer 100A may be either a silicon wafer or a silicon-on-insulator (SOI) wafer. In the latter case, the substrate wafer may, from the back side 100D to the front side 100U, include a base layer, a buried oxide layer and a top silicon layer.

In this embodiment, a plurality of crystal resonators may be formed on the device wafer 100. Accordingly, there may be a plurality of device areas AA defined on the device wafer 100, with the control circuits 110 being formed in the device areas AA.

In step S200, with reference to FIG. 2b, the device wafer 100 is etched so that a lower cavity 120 of the crystal resonator is formed therein. In other words, the lower cavity 120 is exposed at the front side of the device wafer. The lower cavity 120 is formed in order to provide a space in which the subsequently formed piezoelectric vibrator can vibrate.

In this embodiment, the lower cavity 120 is formed in the dielectric layer 100B of the device wafer in the device area AA. Accordingly, the formation of the lower cavity 120 may include etching the dielectric layer 100B until the substrate wafer 100A is reached, so as to form a lower cavity 120 in the dielectric layer 110B. The lower cavity 120 may have a depth as practically required, and the present invention is not limited in this regard. For example, the lower cavity 120 may extend only within the dielectric layer 100B or even into the substrate wafer 100A.

It is to be noted that the relative positions of the lower cavity 120 and the first and second circuits shown in the appended drawings are merely for illustration, and in practice, the arrangement of the first and second circuits may depend on the actual circuit layout requirements. The present invention is not limited in this regard.

As noted above, the substrate wafer 100A may be implemented as a SOI wafer. In this case, the formation of the lower cavity may include successively etching through the dielectric layer and the top silicon layer so that the lower cavity extends from the dielectric layer to the buried oxide layer.

In step S300, with reference to FIGS. 2c to 2d, a piezoelectric vibrator 200 including a top electrode 230, a piezoelectric crystal 220 and a bottom electrode 210 is formed on the surface of the device wafer 100 above the lower cavity 120.

The formation of the piezoelectric vibrator 200 may include the following steps.

Step 1: With reference to FIG. 2c, forming the bottom electrode 210 at a predetermined position on the surface of the device wafer 100. In this embodiment, the formed bottom electrode 210 is located around the lower cavity 120 and covers the first interconnecting structure 111C in the first circuit 111, thus electrically connecting the bottom electrode 210 to the first interconnecting structure 111C. In this way, the bottom electrode 210 can be electrically connected to the first transistor 111T via the first interconnecting structure 111C.

The bottom electrode 210 may be formed of silver by successively performing a thin-film deposition process, a photolithography process and an etching process. Alternatively, the formation of the bottom electrode 210 may be accomplished by a vapor deposition process.

Step 2: With reference to FIG. 2d, bonding a piezoelectric crystal 220 to the bottom electrode 210 so that the piezoelectric crystal 220 is located above the lower cavity 120, with its peripheral edge portions residing on the bottom electrode 210. In this way, part of the piezoelectric crystal 220 corresponds to the lower cavity 120. The piezoelectric crystal 220 may be, for example, a quartz crystal plate.

Step 3: With continued reference to FIG. 2d, forming a top electrode 230 on the piezoelectric crystal 220. With similarity to the bottom electrode 210, the top electrode 230 may also be formed of silver by performing a thin-film deposition process or a vapor deposition process. In a subsequent process, the top electrode 230 is brought into electrical connection with the control circuit.

It is to be noted that, in this embodiment, the bottom electrode 210, the piezoelectric crystal 220 and the top electrode 230 are successively formed over the device wafer 100 using semiconductor processes. However, in other embodiments, it is also possible to form the top and bottom electrodes on opposing sides of the piezoelectric crystal and then bond the three as a whole onto the device wafer.

In step S400, with reference to FIGS. 2e and 2f, a connecting structure is formed on the device wafer 100, which electrically connects the top and bottom electrodes 230, 210 of the piezoelectric vibrator to the control circuit in the device wafer 100. Specifically, the bottom electrode 210 may be electrically connected to the first interconnecting structure in the first circuit, and the top electrode 230 may be electrically connected to the second interconnecting structure in the second circuit.

An electrical signal can be applied to the bottom and top electrodes 210, 230 of the piezoelectric vibrator 200 by the control circuit 110 to create an electric field therebetween, which causes the piezoelectric crystal 220 of the piezoelectric vibrator 200 to change its shape. When the electric field in the piezoelectric vibrator 200 is inverted, the piezoelectric crystal 220 will change its shape in the opposite direction. Therefore, when the control circuit 110 applies an AC signal to the piezoelectric vibrator 200, the piezoelectric crystal 220 will change shape alternately in opposite directions and thus alternately contract and expand due to the change in direction of the electric field. As a result, the piezoelectric crystal 220 will mechanically vibrate.

The connecting structure may include a first connecting member and a second connecting member. The first connecting member connects the first interconnecting structure and the bottom electrode 210 of the piezoelectric vibrator. The second connecting member connects the second interconnecting structure and the top electrode 230 of the piezoelectric vibrator.

In this embodiment, the bottom electrode 210 is formed on the surface of the device wafer 100 and extends beyond the piezoelectric crystal 220 thereunder over the first interconnecting structure 111C. Therefore, it can be considered that the extension of the bottom electrode 210 beyond the piezoelectric crystal constitutes the first connecting member.

Of course, in other embodiments, it is also possible that the first connecting member is formed on the device wafer 100 so as to be electrically connected to the first interconnecting structure prior to the formation of the bottom electrode and brought into electrical connection with the bottom electrode 210 subsequent to the formation of the bottom electrode. In this case, the first connecting member may, for example, include a rewiring layer, which is connected to the first interconnecting structure and is brought into electrical connection with the bottom electrode 210 after the bottom electrode is formed on the device wafer.

Subsequent to the formation of the top electrode 230, the second connecting member may be formed to enable electrical connection between the top electrode 230 and the second circuit 112. The formation of the second connecting member may include the steps detailed below.

At first, with reference to FIG. 2e, an encapsulation layer 300 is formed on the device wafer 100. In this embodiment, the encapsulation layer 300 covers the piezoelectric crystal 220, with the top electrode 230 being exposed from the encapsulation layer. Examples of materials from which the encapsulation layer 300 can be made may include polyimide.

Next, with continued reference to FIG. 2e, a through hole 300a is formed in the encapsulation layer 300. In this embodiment, the through hole 300a extends through the encapsulation layer 300 so that the second interconnecting structure 112C is exposed in the through hole.

Subsequently, with reference to FIG. 2f, a conductive material is filled in the through hole 300a, resulting in the formation of a conductive plug 310, which is electrically connected to the second interconnecting structure 112C at the bottom and exposed from the encapsulation layer at the top.

Afterward, with continued reference to FIG. 2f, an interconnecting wire 320 is formed on the encapsulation layer 300 and covers the top electrode 230 at one end and covers the conductive plug 310 at the other end, and the encapsulation layer 300 is then removed so that the top electrode 230 is connected to the second circuit 112 via the interconnecting wire 320 and the conductive plug 310.

Of course, alternatively, the top electrode may be formed on the piezoelectric crystal so as to have an extension extending beyond the piezoelectric crystal. In this case, the conductive plug of the second connecting member may be formed under the extension of the top electrode so that it is connected to the second interconnecting structure at the bottom and connected to, and thus provides support for, the extension of the top electrode at the top.

Alternatively, the conductive plug of the second connecting member may be formed prior to the formation of the top electrode. Specifically, the formation of the top electrode and the conductive plug of the second connecting member may include the steps detailed below.

At first, a encapsulation layer is formed on the device wafer 100. Specifically, the encapsulation layer may cover the device wafer 100, with the piezoelectric crystal 220 being exposed from the encapsulation layer.

Next, a through hole is formed in the encapsulation layer and a conductive material is filled in the through hole, resulting in the formation of the conductive plug, which is electrically connected to the second interconnecting structure 112C.

Afterward, the top electrode is formed on the piezoelectric crystal 220 so that it covers at least part of the piezoelectric crystal 220 and extends beyond the piezoelectric crystal 220 over the conductive plug. As a result, the top electrode is electrically connected to the second interconnecting structure 112C via the conductive plug 310.

In step S500, with reference to FIGS. 2g to 2i, a cap layer 420 is formed on the surface of the device wafer 100 and covers the piezoelectric vibrator 200 and delimits an upper cavity 400 of the crystal resonator together with the piezoelectric vibrator 200 and the device wafer 100.

Specifically, the formation of the cap layer 420 that delimits the upper cavity 400 may include, for example, the steps detailed below.

In a first step, with reference to FIG. 2g, a sacrificial layer 410 is formed on the surface of the device wafer 100 and covers the piezoelectric vibrator 200.

In a second step, with continued reference to FIG. 2g, a cap material layer 421 is formed over the surface of the device wafer 100 and wraps the sacrificial layer 410 by covering its top and side surfaces.

The space occupied by the sacrificial layer 410 corresponds to the internal space of the subsequently formed upper cavity. Therefore, a depth of the upper cavity to be formed may be adjusted by changing a height of the sacrificial layer. It will be recognized that the depth of the upper cavity may be determined as practically required, and the present invention is not limited in this regard.

In a third step, with reference to FIG. 2h, at least one opening 420a is formed in the material layer 421, thus resulting in the formation of the cap layer 420. The sacrificial layer 410 is exposed in the opening 420a.

In a fourth step, with reference to FIG. 2i, the sacrificial layer 410 is removed via the opening 420a, resulting in the formation of the upper cavity 400.

At this point, the piezoelectric vibrator 200 is confined in the upper cavity 400 so that the piezoelectric vibrator 200 can vibrate within the lower and upper cavities 120, 400.

Optionally, with reference to FIG. 2j, the method may further include closing the opening in the cap layer 420, so as to close the upper cavity, thus enclosing the piezoelectric vibrator within the upper cavity. Specifically, the enclosure of the upper cavity 400 can be accomplished by closing the opening with a closure plug 430.

An integrated structure of a crystal resonator and a control circuit corresponding to the above method will be described below with reference to FIG. 2i. The integrated structure of the crystal resonator and the control circuit includes:

a device wafer 100 in which the control circuit and a lower cavity 120 are formed, the lower cavity 120 being exposed at a front side of the device wafer;

a piezoelectric vibrator 200 formed on the front side of the device wafer 100 above the lower cavity 120;

a connecting structure configured to electrically connect a top electrode 210 and a bottom electrode 230 of the piezoelectric vibrator 200 to the control circuit, wherein the control circuit is able to apply to an electrical signal to the piezoelectric vibrator 200 to cause the piezoelectric vibrator 200 to vibrate; and

a cap layer 420 formed on the front side of the device wafer 100 so as to cover the piezoelectric vibrator 200 and delimit an upper cavity 400 together with the piezoelectric vibrator 200 and the device wafer 100. That is, the cap layer 420 encloses the piezoelectric vibrator 200 within the upper cavity 400.

Therefore, the integration of the crystal resonator with the control circuit is accomplished by forming the lower cavity 120 in the device wafer 100 and forming the cap layer 420 using a semiconductor process, which encloses the piezoelectric vibrator 200 within the upper cavity 400 so that it is ensured that the piezoelectric vibrator 200 can oscillate in the upper and lower cavities 400, 120. This is favorable to on-chip modulation for correcting raw deviations of the crystal resonator such as temperature and frequency drifts. Further, the crystal resonator fabricated based on the semiconductor processes is more compact in size and is thus less power-consuming.

With continued reference to FIG. 2j, the control circuit may include a first circuit 111 and a second circuit 112, which may be electrically connected to the top and bottom electrodes of the piezoelectric vibrator 200 respectively. The first circuit 111 may include a first transistor 111T and a first interconnecting structure 111C. The first transistor 111T may be buried within the device wafer 100, and the first interconnecting structure 111C may be connected to the first transistor 111T and extend to the front side of the device wafer 100. The second circuit 112 may include a second transistor 1121 and a second interconnecting structure 112C. The second transistor 112T may be buried within the device wafer 100, and the second interconnecting structure 112C may be connected to the second transistor 112T and extend to the front side of the device wafer 100.

The connecting structure may include a first connecting member connecting the first interconnecting structure 111C and the bottom electrode 210 of the piezoelectric vibrator, and a second connecting member connecting the second interconnecting structure 112C and the top electrode 230 of the piezoelectric vibrator.

In this embodiment, the bottom electrode 210 is formed on the surface of the device wafer 100 so as to be located at the periphery of the lower cavity 120 and have an extension extending laterally beyond the piezoelectric crystal 220 over the first interconnecting structure 111C in the first circuit 111. As such, the bottom electrode 210 is electrically connected to the first circuit 111. Therefore, it can be considered that the extension of the bottom electrode 210 beyond the piezoelectric crystal constitutes the first connecting member.

The top electrode 230 may be formed on the piezoelectric crystal 220 and electrically connected to the second interconnecting structure 112C of the second circuit 112 via the second connecting member. Specifically, the second connecting member for connecting the top electrode 230 and the second circuit 112 may include a conductive plug 310 and an interconnecting wire 320. The conductive plug 310 may be formed on the surface of the device wafer 100 so as to be electrically connected at the bottom to the second interconnecting structure 112C. The interconnecting wire 320 may cover the top electrode 230 at one end and cover the top of the conductive plug 310 at the other end. In this way, the interconnecting wire 320 can be connected to the conductive plug 310. It will be appreciated that, in this case, the conductive plug 310 may also function to support the interconnecting wire 320,

In other embodiments, the second connecting member may only include the conductive plug. In this case, the conductive plug may be electrically connected to the top electrode 230 at one end and to the second interconnecting structure 112C at the other end. For example, the top electrode may extend from the piezoelectric crystal to the conductive plug.

With continued reference to FIG. 2j, in this embodiment, the device wafer 100 includes a substrate wafer 100A and a dielectric layer 100B. The first transistor 111T and the second transistor 112T are both formed on the substrate wafer 100A, and the dielectric layer 100B is so formed on the substrate wafer 100A as to cover both the first transistor 111T and the second transistor 112T. In addition, both the first interconnecting structure 111C and the second interconnecting structure 112C are formed in the dielectric layer 100B. Further, the lower cavity 120 extends through the dielectric layer 100B up to the substrate wafer 100A. That is, the lower cavity 120 is formed in the dielectric layer 100B accordingly.

With continued reference to FIG. 2j, in this embodiment, at least one opening is formed in the cap layer 420, and a closure plug 430 is fitted in each opening. As such, the upper cavity 400 is closed to enclose the piezoelectric vibrator 200 therein.

In summary, in the method for integrating the crystal resonator with the control circuit according to the present invention, the integration of the crystal resonator with the control circuit is accomplished by first forming the lower cavity in the device wafer containing the control circuit, forming the piezoelectric vibrator on the device wafer and then enclosing the piezoelectric vibrator within the upper cavity through forming the cap layer using a planar fabrication process. Apparently, compared with traditional crystal resonators (e.g., surface-mount ones), in addition to being able to integrate with other semiconductor components more easily with a higher degree of integration, the crystal resonator of the present invention that is fabricated using planar fabrication processes is more compact in size and hence less power-consuming.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer in which a control circuit is formed, and etching the device wafer to form a lower cavity for the crystal resonator;
forming a piezoelectric vibrator comprising a top electrode, a piezoelectric crystal and a bottom electrode on a front side of the device wafer above the lower cavity;
forming a connecting structure on the device wafer, wherein the connecting structure electrically connects the top electrode and the bottom electrode of the piezoelectric vibrator to the control circuit; and
forming a cap layer on the front side of the device wafer, wherein the cap layer covers the piezoelectric vibrator, and the cap layer together with the piezoelectric vibrator and the device wafer delimits an upper cavity for the crystal resonator.

2. The method for integrating a crystal resonator with a control circuit according to claim 1, wherein the device wafer comprises a substrate wafer and a dielectric layer formed on the substrate wafer, and wherein the lower cavity is formed in the dielectric layer.

3. The method for integrating a crystal resonator with a control circuit according to claim 2, wherein the substrate wafer is a silicon-on-insulator substrate comprising a base layer, a buried oxide layer and a top silicon layer, which are sequentially stacked from a back side to the front side of the substrate wafer, and wherein the lower cavity extends from the dielectric layer to the buried oxide layer.

4. The method for integrating a crystal resonator with a control circuit according to claim 1, wherein the formation of the piezoelectric vibrator comprises:
forming the bottom electrode at a predetermined position on a surface of the device wafer; bonding the piezoelectric crystal to the bottom electrode; and forming the top electrode on the piezoelectric crystal, or
forming the top electrode and the bottom electrode of the piezoelectric vibrator on the piezoelectric crystal; and bonding the top electrode, the piezoelectric crystal and the bottom electrode as a whole to the device wafer.

5. The method for integrating a crystal resonator with a control circuit according to claim 4, wherein the formation of the bottom electrode comprises a vapor deposition process or a thin-film deposition process, and wherein the formation of the top electrode comprises a vapor deposition process or a thin-film deposition process.

6. The method for integrating a crystal resonator with a control circuit according to claim 1, wherein the control circuit comprises a first interconnecting structure and a second interconnecting structure, and the connecting structure comprises a first connecting member and a second connecting member,
wherein the first connecting member is connected to the first interconnecting structure and the bottom electrode of the piezoelectric vibrator, and the second connecting member is connected to the second interconnecting structure and the top electrode of the piezoelectric vibrator;
wherein the bottom electrode is formed on a surface of the device wafer and extends beyond the piezoelectric crystal thereunder to come into electrical connection with the first interconnecting structure, and the extension of the bottom electrode beyond the piezoelectric crystal constitutes the first connecting member.

7. (canceled)

8. The method for integrating a crystal resonator with a control circuit according to claim 6, wherein the first connecting member is formed on the device wafer so as to be electrically connected to the first interconnecting structure prior to the formation of the bottom electrode and brought into electrical connection with the bottom electrode subsequent to the formation of the bottom electrode.

9. The method for integrating a crystal resonator with a control circuit according to claim 8, wherein the first connecting member comprises a rewiring layer connected to the first interconnecting structure, and wherein the rewiring layer is brought into electrical connection with the bottom electrode subsequent to the formation of the bottom electrode.

10. The method for integrating a crystal resonator with a control circuit according to claim 6, wherein the formation of the second connecting member comprises:
forming an encapsulation layer on the device wafer;
forming a through hole in the encapsulation layer and filling a conductive material in the through hole, to form a conductive plug having a bottom portion electrically connected to the second interconnecting structure and a top portion exposed from the encapsulation layer;
forming the top electrode which extends beyond the piezoelectric crystal to the top portion of the conductive plug to bring the top electrode into electrical connection with the conductive plug, or forming the top electrode, then forming an interconnecting wire on the encapsulation layer, the interconnecting wire having one end covering the top electrode and a further end covering the conductive plug; and
removing the encapsulation layer.

11. The method for integrating a crystal resonator with a control circuit according to claim 1, wherein the formation of the cap layer delimiting the upper cavity comprises:
forming a sacrificial layer on a surface of the device wafer to cover the piezoelectric vibrator;
forming a cap material layer over the surface of the device wafer to warp the sacrificial layer by covering top and side surfaces of the sacrificial layer; and
forming at least one opening in the cap material layer to form the cap layer, and removing the sacrificial layer via the opening in which the sacrificial layer is exposed so as to form the upper cavity.

12. The method for integrating a crystal resonator with a control circuit according to claim 11, further comprising, subsequent to the formation of the upper cavity,
closing the opening in the cap layer to close the upper cavity and enclose the piezoelectric vibrator within the upper cavity.

13. An integrated structure of a crystal resonator and a control circuit, comprising:
a device wafer in which the control circuit and a lower cavity are formed, wherein the lower cavity is exposed at a front side of the device wafer;
a piezoelectric vibrator comprising a top electrode, a piezoelectric crystal and a bottom electrode, wherein the piezoelectric vibrator is formed on the front side of the device wafer above the lower cavity;
a connecting structure configured to electrically connect the top electrode and the bottom electrode of the piezoelectric vibrator to the control circuit; and
a cap layer which is formed on the front side of the device wafer and covers the piezoelectric vibrator, wherein the cap layer together with the piezoelectric vibrator and the device wafer delimits an upper cavity for the crystal resonator.

14. The integrated structure of a crystal resonator and a control circuit according to claim 13, wherein the device wafer comprises a substrate wafer and a dielectric layer formed on the substrate wafer, and wherein the lower cavity is formed in the dielectric layer.

15. The integrated structure of a crystal resonator and a control circuit according to claim 14, wherein the substrate wafer is a silicon-on-insulator substrate comprising a base layer, a buried oxide layer and a top silicon layer, which are sequentially stacked from a back side to the front side of the substrate wafer, and wherein the lower cavity extends from the dielectric layer to the buried oxide layer.

16. The integrated structure of a crystal resonator and a control circuit according to claim 13, wherein the control circuit comprises a first interconnecting structure and a second interconnecting structure, and the connecting structure comprises a first connecting member and a second connecting member,
wherein the first connecting member is connected to the first interconnecting structure and the bottom electrode of the piezoelectric vibrator, and the second connecting member is connected to the second interconnecting structure and the top electrode of the piezoelectric vibrator.

17. The integrated structure of a crystal resonator and a control circuit according to claim 16, wherein the bottom electrode is formed on a surface of the device wafer and extends beyond the piezoelectric crystal thereunder to come into electrical connection with the first interconnecting structure, and the extension of the bottom electrode beyond the piezoelectric crystal constitutes the first connecting member.

18. The integrated structure of a crystal resonator and a control circuit according to claim 16, wherein the second connecting member comprises a conductive plug having an end electrically connected to the top electrode and a further end electrically connected to the second interconnecting structure.

19. The integrated structure of a crystal resonator and a control circuit according to claim 16, wherein the second connecting member comprises:
a conductive plug which is formed on a surface of the device wafer and has a bottom portion connected to the second interconnecting structure; and
an interconnecting wire which has an end covering the top electrode and a further end covering a top portion of the conductive plug, so that the interconnecting wire comes into connection with the conductive plug.

20. The integrated structure of a crystal resonator and a control circuit according to claim 16, wherein the control circuit further comprises a first transistor and a second transistor, and wherein the first transistor is connected to the first interconnecting structure, and the second transistor is connected to the second interconnecting structure.

21. The integrated structure of a crystal resonator and a control circuit according to claim 13, wherein at least one opening in which a closure plug is fitted for closing the upper cavity is formed in the cap layer.
